(19) United States
(12) Patent Application Publication
(10) Pub. No.: US 2026/0196981 A1
(43) Pub. Date: Jul. 9, 2026

(54) RF FILTER INCLUDING ACOUSTIC WAVE DEVICES AND METHOD OF MANUFACTURING THE SAME

(71) Applicant: WISOL CO., LTD., Osan-si (KR)

(72) Inventor: Tae Hyun KIM, Osan-si (KR)

(73) Assignee: WISOL CO., LTD., Osan-si (KR)

(21) Appl. No.: 19/404,039

(22) Filed: Dec. 1, 2025

(30) Foreign Application Priority Data
Jan. 8, 2025 (KR) 10-2025-0003098

(51) Int. Cl. H03H 9/54; H03H 3/02; H03H 9/13

(52) U.S. Cl. CPC H03H 9/54; H03H 3/02; H03H 9/133

(57) ABSTRACT

The present invention relates to an RF filter and a method of manufacturing the same, wherein the RF filter according to one embodiment may include a support substrate having a plurality of cavities; a piezoelectric plate disposed on the support substrate; a conductive pattern disposed on the piezoelectric plate and comprising at least one IDT electrode; an open line trench exposing a peripheral of the support substrate; and at least one first connection hole communicating the cavity with the open line trench.

### CROSS-REFERENCES TO RELATED APPLICATION

The present application claims, under 35 U.S.C. § 119(a), the benefit of Korean Patent Application No. 10-2025-0003098, filed on Jan. 8, 2025 which is hereby incorporated by reference in its entirety.

### BACKGROUND

### 1. Field

The present invention relates to filter technology, and more particularly to an RF filter comprising a plurality of acoustic wave devices and a method of manufacturing the same.

### 2. Description of the Related Art

Radio frequency (RF) filters are devices that pass some frequencies and block others, and are used in wireless communication systems, for example in cellular base stations, mobile phones, and computing devices. “Pass” means to transmit with relatively low signal loss, while “block” means to transmit with attenuated signal. The frequency range that an RF filter passes through is called the filter's “passband,” and the frequency range that it blocks is called the filter's “cutoff band.” A typical RF filter has at least one passband and at least one blocking band. The specific requirements for the passband or blocking band may vary depending on the specific application. For example, a “passband” may be defined as a frequency range in which the insertion loss of the filter is less than a defined value, such as 1 dB, 2 dB, or 3 dB. The “cutoff band” may be defined as the frequency range where the insertion loss of the filter is greater than a defined value, such as 20 dB, 30 dB, 40 dB or more, depending on the application.

The next generation of mobile communications, 6G mobile communications, is being researched and developed, which aims to utilize ultra-high frequency bands and THz frequencies to support faster terabit (Tbps) data rates than conventional mobile communications, and to minimize latency (e.g., 0.1 ms latency) to provide real-time interaction between communications and connected devices. Currently, high-performance RF filters for communication systems typically utilize surface acoustic wave (SAW) resonators, bulk acoustic wave (BAW) resonators, and film bulk acoustic wave resonators (FBAR). However, these prior art technologies are not suitable for use in next-generation mobile communications utilizing ultra-high frequency bands and THz frequencies.

Therefore, there is a need for research on an RF filter comprising a plurality of elastic wave elements suitable for high bandwidth and high frequency without performance degradation while satisfying the required characteristics of the element through a simple fabrication process.

### SUMMARY

The technical challenge of the present invention is to provide an RF filter comprising a plurality of elastic wave elements suitable for high bandwidth and high frequency without performance degradation while satisfying the required characteristics of the element through a simple manufacturing process.

Furthermore, it is to provide an RF filter that may minimize the breakage of a piezoelectric plate, thereby minimizing the distortion of acoustic waves excited by the damage of the piezoelectric plate.

Furthermore, the present invention aims to provide a method of manufacturing such an RF filter.

The problems to be solved by the present invention are not limited to those mentioned above, and other problems not mentioned may be understood by those skilled in the art from the following description.

According to one embodiment of the present invention, there may be provided an RF filter comprising a support substrate having a plurality of cavities; a piezoelectric plate disposed on the support substrate; a conductive pattern disposed on the piezoelectric plate and comprising at least one IDT electrode; an open line trench exposing a peripheral of the support substrate; and at least one first connection hole communicating the cavities with the open line trench.

In one embodiment, the open line trench may have a step between the piezoelectric plate and the support substrate, the step may be equal to or greater than the sum of a thickness of the piezoelectric plate and a height of the first connection hole. The open line trench may have a predetermined width and may be formed along a peripheral of the support substrate. The first connecting hole may be in a direction perpendicular to a thickness direction of the support substrate. A height of the first connecting hole may be less than or equal to a height of the cavity. The height of the first connecting hole may be from 0.2 times to 1.0 times of the height of the open line trench. The width of the first connecting hole may be from 0.1 times to 0.9 times of the width of the cavity.

A region of the piezoelectric plate overlapping the at least one cavity and an IDT electrode disposed in the region of the piezoelectric plate is defined as a single bulk elastic wave element, and the RF filter may comprise a plurality of bulk elastic wave elements. If the bulk elastic wave element comprises two cavities spaced apart from each other, it may further comprise a second connecting hole communicating between the two cavities in the bulk elastic wave element.

The piezoelectric substrate comprises any one of lithium niobate (LiNbO3), lithium tantalate, lanthanum gallium silicate, gallium nitride, or aluminum nitride, zinc oxide, or lead titanate (PZT), wherein the IDT electrode comprises any one of aluminum (Al), copper (Cu), platinum (Pt), gold (Au), silver (Ag), titanium (Ti), nickel (Ni), chromium (Cr), molybdenum (Mo), tungsten (W), or an alloy based on any one of these metals, and wherein the support substrate may comprise any one of silicon (Si), quartz, glass, silicon carbide (SiC), or sapphire.

The RF filter may be any one of a band reject filter, a band pass filter, a duplexer, and a multiplexer.

According to another embodiment of the invention, a method of manufacturing an RF filter comprises preparing a support substrate having at least one cavity and at least one first connection hole; filling the cavity and the first connection hole with a sacrificial material; forming a piezoelectric plate on the support substrate filled with the sacrificial material; forming an open line trench along a perimeter of the support substrate such that the perimeter of the support substrate is exposed; and etching to remove the sacrificial material filled in the cavity and the first connecting hole communicating with the open line trench, wherein a first end of the first connecting hole may be open through the open line trench. It may further comprise the step of forming a conductive pattern on a region of the piezoelectric plate overlapping the cavity.

The sacrificial material may be a silicon oxide film or photoresist. The support substrate may further comprise a second connecting hole communicating between the two adjacent cavities. The height of the first connecting hole may be less than or equal to the height of the cavities. The height of the first connecting hole may be from 0.2 times to 1.0 times the height of the open line trench. The width of the first connecting hole may be from 0.1 times to 0.9 times the width of the cavity.

According to another embodiment of the present invention, there may be provided an elastic wave element comprising a support substrate having at least one cavity; a piezoelectric plate disposed on the support substrate; at least one IDT electrode disposed on the piezoelectric plate; and at least one first connecting hole communicating the cavity with the outside and perpendicular to a thickness direction of the piezoelectric plate.

According to one embodiment of the present invention, an RF filter and a method of manufacturing an RF filter comprising a plurality of elastic wave elements suitable for high bandwidth and high frequency without performance degradation while satisfying the required characteristics of the device through a simple manufacturing process may be provided.

Further, by including an open line trench exposing a peripheral of a support substrate and at least one first connection hole communicating a cavity with the open line trench, the RF filter may minimize damage to a piezoelectric plate, thereby minimizing distortion of an acoustic wave excited due to damage to the piezoelectric plate, and may satisfy the required characteristics of a resonator.

However, the effects of the present invention are not limited to the above effects, and may be expanded in various ways without departing from the technical ideas and scope of the present invention.

### BRIEF DESCRIPTION OF THE DRAWINGS

FIG. 1 illustrates a top view of an RF filter comprising a plurality of elastic wave elements, according to one embodiment of the present invention.

FIGS. 2a and 2b illustrate perspective views of an RF filter comprising a plurality of elastic wave elements, according to one embodiment of the present invention.

FIGS. 3a to 3c illustrate cross-sectional views of an RF filter comprising a plurality of elastic wave elements, according to one embodiment of the present invention.

FIGS. 4a through 9e illustrate a manufacturing method of an RF filter comprising a plurality of elastic wave elements according to one embodiment of the present invention.

### DETAILED DESCRIPTION

Hereinafter, embodiments of the present invention will be described in detail with reference to the accompanying drawings.

The embodiments of the invention described below are provided to make the invention more clear to those having ordinary knowledge in the art, and the scope of the invention is not limited by the following embodiments, and the following embodiments may be modified in various other forms.

The terms used herein are intended to describe specific embodiments and are not intended to limit the invention. Terms used herein in the singular form may include the plural form, unless the context clearly indicates otherwise. Furthermore, the terms “comprise” and/or “comprising” as used herein are intended to specify the presence of the mentioned shapes, steps, numbers, motions, absences, elements, and/or groups thereof, and are not intended to exclude the presence or addition of one or more other shapes, steps, numbers, motions, absences, elements, and/or groups thereof. Furthermore, as used herein, the term “connected” is intended to mean not only that certain elements are directly connected, but also that they are indirectly connected by the interposition of other elements between them.

Furthermore, when the present disclosure refers to a member being located “on” another member, this includes not only when a member abuts another member, but also when there is another member between the two members. As used herein, the term “and/or” includes any one of the enumerated items and any combination of one or more of them. In addition, the terms “about,” “substantially,” and the like as used herein are intended to mean at or near the range of values or degrees, taking into account inherent manufacturing and material tolerances, and to prevent infringers from taking unfair advantage of the disclosure where precise or absolute figures are provided for the purpose of illustration.

Embodiments of the present invention will now be described in detail with reference to the accompanying drawings. The sizes or thicknesses of the areas or parts shown in the accompanying drawings may be somewhat exaggerated for clarity and ease of description. Throughout the detailed description, like reference numerals refer to like components.

Recently, transversely excited film bulk acoustic resonators (laterally excited bulk wave resonator (XBAR)) suitable for high bandwidth and high frequency have been researched and developed. These XBARs include an interdigital transducer (IDT) formed on a thin floating layer or diaphragm of piezoelectric material. A microwave signal applied to the IDT excites a shear fundamental acoustic wave within the piezoelectric diaphragm such that the acoustic energy flows in a direction orthogonal to or transverse to the direction of the electric field generated by the IDT, i.e., substantially perpendicular to the surface of the layer. Furthermore, the XBAR may provide very high electromechanical coupling and high frequency capability above conventional resonance.

The resonant frequency of such an XBAR may be determined by the thickness of the piezoelectric diaphragm overlapping the cavity. One side of the piezoelectric diaphragm may be exposed or closed by the cavity. Specifically, if one side of the piezoelectric diaphragm is exposed by the cavity, a piezoelectric layer may be formed on one side of a support substrate and then an open cavity may be formed on the other side of the support substrate by an etching process, or an open cavity may first be formed on one side of the support substrate by an etching process and then a piezoelectric layer may be bonded to the base substrate having the open cavity. If a first side of the piezoelectric diaphragm is closed by the cavity, a closed cavity may be formed between the support substrate and the piezoelectric layer by forming an etching hole overlapping a portion of the cavity after the piezoelectric layer is formed on a first side of the support substrate filled with a sacrificial layer in the cavity, and removing the sacrificial layer in the cavity through the etching hole.

However, since the etching hole penetrates the piezoelectric layer overlapping the cavity, the piezoelectric diaphragm exciting the shear fundamental acoustic wave is damaged. Due to the damage of the piezoelectric diaphragm, the excited fundamental acoustic wave may be distorted, which may make it difficult to satisfy the required characteristics of the resonator. In addition, the size of the device may increase because a separate space is required to form an etched hole on the top surface.

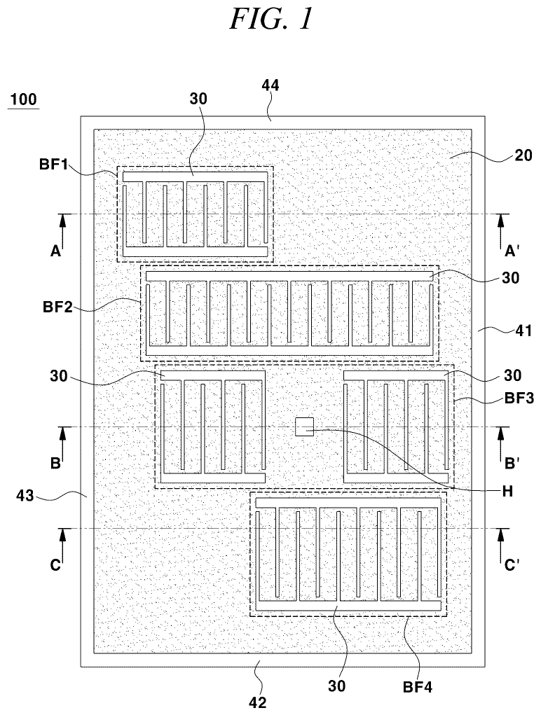

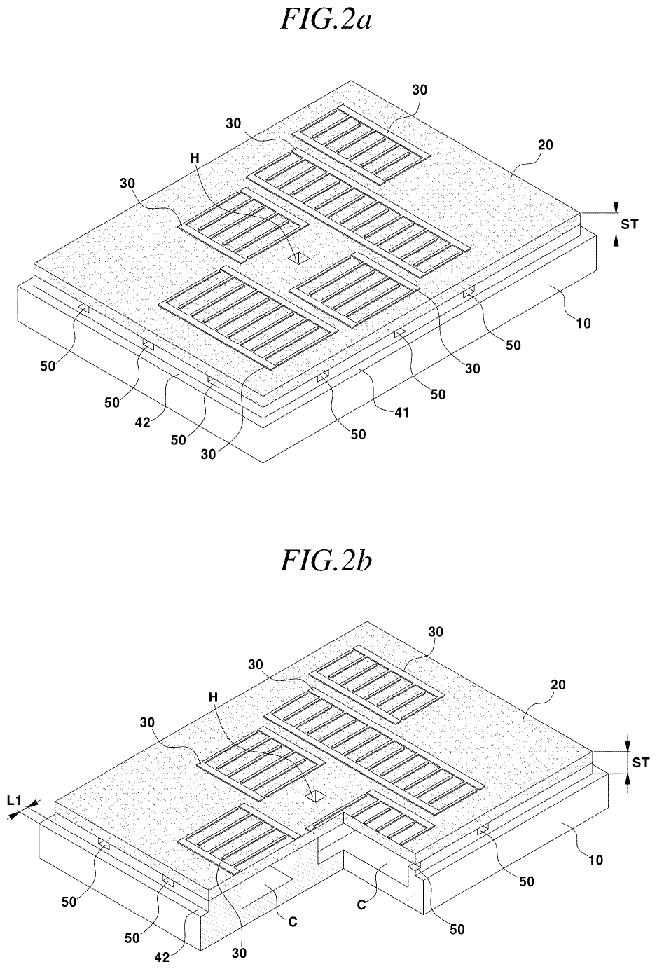

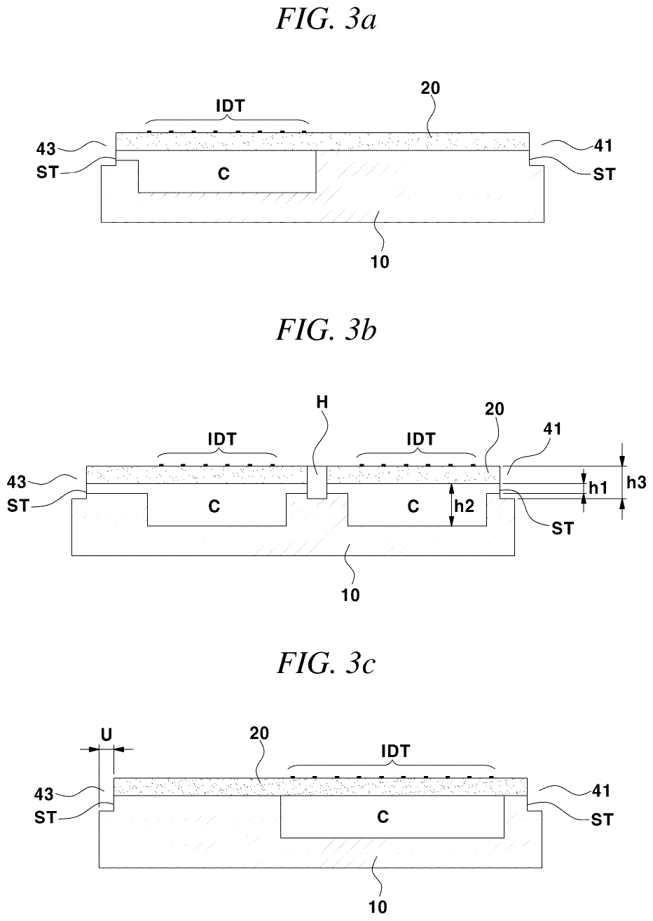

FIG. 1 illustrates a plan view of an RF filter 100 comprising a plurality of elastic wave elements according to one embodiment of the present invention, FIGS. 2a and 2b illustrate perspective views of an RF filter 100 comprising a plurality of elastic wave elements according to one embodiment of the present invention, and FIGS. 3a to 3c illustrate cross-sectional views of an RF filter 100 comprising a plurality of elastic wave elements according to one embodiment of the present invention.

Referring to FIGS. 1, 2a and 2b, the RF filter 100 comprises a support substrate 10 having a plurality of cavities C, a piezoelectric plate 20 disposed on the support substrate 10, and a conductive pattern 30 disposed on the piezoelectric plate 20 and including at least one IDT electrode, an open line trench 41, 42, 43, 44 exposing a peripheral of the support substrate 10, and at least one first connection hole 50 communicating the cavity C with the open line trench. The open line trenches may include a first open line trench 41, a second open line trench 42, a third open line trench 43, and a fourth open line trench 44.

In one embodiment, the support substrate 10 may include a plurality of cavities C that form a space adjacent to or in contact with one surface of the piezoelectric plate 20 as a substrate for supporting the piezoelectric plate 20, and a plurality of first connection holes 50 that communicate the cavities C with the open line trenches. The support substrate 10 may be non-limitingly silicon (Si), quartz, glass, silicon carbide (SiC), sapphire, AIN, or any other material. For example, the support substrate 10 may include a silicon oxide layer or a crystalline silicon layer. While FIGS. 1, 2a, and 2b exemplarily show five cavities C and five first connection holes 50, the present invention is not limited thereto, and the support substrate 10 may include fewer than five or more than cavities C and the first connection holes 50. In addition, the support substrate 10 may further include a second connecting hole (not shown) communicating between the two cavities.

In one embodiment, the piezoelectric plate 20 may be composed of lithium niobate (LiNbO₃). However, the material of the piezoelectric plate 20 is not limited to the above, and may be, for example, lithium tantalate, lanthanum gallium silicate, gallium nitride, or aluminum nitride, zinc oxide, or lead titanate (PZT). The thickness of the piezoelectric plate 20 formed on one side of the support substrate 10 may range from 10 nm to 500 nm. If the thickness of the piezoelectric plate 20 is 10 nm or less, it may be difficult to handle during the manufacturing process and may break easily, and if it is 500 nm or more, it may be difficult to realize an RF filter that operates in the desired high and high frequency bands. The support substrate 10 also has a smaller coefficient of thermal expansion than the piezoelectric plate 20. By attaching the support substrate 10, which has a smaller coefficient of thermal expansion than the piezoelectric plate 20, to the piezoelectric plate 20, changes in the size of the piezoelectric plate 20 when the temperature changes may be suppressed, thereby suppressing changes in the frequency characteristics of the RF filter 100. Also, preferably, the piezoelectric plate 20 may be a single crystal layer.

In one embodiment, the conductive pattern 30 may comprise a plurality of IDT electrodes. While FIGS. 1, 2a, and 2b illustrate five IDT electrodes as an example, the conductive pattern 30 may include fewer than five or more than five IDT electrodes.

The plurality of IDT electrodes may extend crosswise over each other in the orthogonal direction of the field direction (x-axis direction), with one end of the IDT electrodes connected to the busbar electrodes to form a comb pattern. The IDT electrode may be non-limitingly aluminum, copper, platinum, Pt, gold, Au, silver, Ag, titanium, nickel, Ni, chromium, Cr, molybdenum, Mo, tungsten, or an alloy based on any one of these metals. The IDT electrode may further include an offset electrode (not shown) opposed in a direction orthogonal to the other end of the IDT electrode. The IDT electrode may be connected to the busbar electrode at the top and the offset electrode (not shown) may be connected to the busbar electrode at the bottom and arranged to oppose each other. The offset electrodes may have a range that is less than the length of the IDT electrodes. The intersection area between the IDT electrodes and the intersection area between the offset electrodes and the area corresponding to the thickness of the busbar electrodes may have different field velocities. Depending on the type of metal, the thickness of the IDT electrodes may vary, and the width of the IDT electrodes may be determined based on the required performance of the filter.

In one embodiment, the open line trenches 41, 42, 43, 44 have a predetermined width L1 and are formed along the perimeter of the support substrate 10, which may include, by way of non-limitation, four open line trenches 41, 42, 43, 44 if the support substrate 10 is square. The open line trench 41 may be formed along a right peripheral of the support substrate 10, the open line trench 43 may be formed along a left peripheral of the support substrate 10, the open line trench 42 may be formed along a bottom peripheral of the support substrate 10, and the open line trench 44 may be formed along a top peripheral of the support substrate 10. The ends of the open line trenches 41 to 44 may or may not be connected to each other, and only one of the open line trenches 41 to 44 may be disposed in accordance with the placement of the cavity C or IDT electrodes.

The open line trenches are arranged to have a step ST between the piezoelectric plate 20 and the support substrate 10. The step ST may be equal to or greater than the sum of the thickness of the piezoelectric plate 20 and the height h1 of the first connection hole. In the etching process to be described later, a portion of the support substrate 10 may be etched so that the step ST is greater than the sum of the thickness of the piezoelectric plate 20 and the height h1 of the first connecting hole.

Non-limitingly, the first connecting hole 50 connecting the cavity C with the open line trenches 41, 42, 43, 44 may vary depending on the number and arrangement of the open line trenches 41 to 44 and the arrangement of the cavity C or IDT electrodes. For example, the first connection hole 50 may be associated with any one of the open line trenches 41, 42, 43, and 44. The first connection hole 50 is in a direction perpendicular to the thickness direction of the support substrate 10, and the height H1 of the first connection hole 50 may be less than or equal to the height H2 of the cavity. Further, the height H1 of the first connecting hole 50 may be 0.2 times to 1.0 times of the height of the open line trench H3. The height h3 of the open line trench h3 may be equal to the size of the step ST. If the height h1 of the first connection hole 50 is 0.2 times or less than the height of the open line trench h3, it becomes difficult to remove the sacrificial material filled in the cavity C via the etching gas or etching solution, and if the height h1 of the first connection hole 50 is 1.0 times or more than the height of the open line trench h3, additional processes are required, which may increase the process cost. Further, the width L2 of the first connecting hole 50 may be 0.1 times to 0.9 times of the width L3 of the cavity C. If the width L2 of the first connecting hole 50 is less than or equal to 0.1 times the width L3 of the cavity C, it becomes difficult to remove the sacrificial material in the cavity C through the etching gas or etching solution, and if the width L2 of the first connecting hole 50 is greater than or equal to 0.9 times or more of the width L2 of the cavity C, the asymmetry with respect to the left and right sides of the cavity C increases, resulting in a decrease in the performance of the filter and a weakening of the stability of the structure, and may require a subsequent process to fill the holes.

In one embodiment, a region of the piezoelectric plate 20 overlapping the at least one cavity C and an IDT electrode disposed in the region of the piezoelectric plate 20 may be defined as a single bulk elastic wave element. For example, referring to FIG. 3a, a region of the base substrate 10 having one cavity C, a region of the piezoelectric plate 20 overlapping the one cavity C, and one IDT electrode disposed in the region of the piezoelectric plate 20 may constitute one bulk elastic wave element BF1. Referring to FIG. 3b, a region of the base substrate 10 having two cavities C, a region of the piezoelectric plate 20 overlapping the two cavities C, and two IDT electrodes disposed in the region of the piezoelectric plate 20 may constitute one bulk elastic wave element BF3. Referring to FIG. 3c, a region of the base substrate 10 having one cavity C, a region of the piezoelectric plate 20 overlapping the one cavity C, and one IDT electrode disposed in the region of the piezoelectric plate 20 may constitute one bulk elastic wave element BF4. In FIGS. 1 and 2a, the RF filter 100 may comprise four bulk elastic wave elements BF1 to BF4. However, the present disclosure is not limited thereto and the RF filter 100 may comprise less than four or more than four bulk elastic wave elements.

Furthermore, as shown in FIG. 3b, when the bulk elastic wave element BF3 comprises two cavities C spaced apart from each other, it may further comprise a second connecting hole 51 communicating between the two cavities C in the bulk elastic wave element BF3. The first connecting hole 50 and the second connecting hole 51 allow for symmetrical and stable removal of the sacrificial material from the cavities C in the bulk elastic wave element BF3 during the etching process to be described later. The second connecting hole 51 may be exposed to the outside through an etch hole H.

In the present invention, the RF filter 100 may be any one of a band reject filter, a band pass filter, a duplexer, and a multiplexer.

Regarding the operation of the elastic wave elements BF1 to BF4 of the present invention, when an RF signal is applied to the IDT electrodes, the RF signal may generate a time-varying electric field between the IDT electrodes. The direction of the electric field may be in the x-direction, or in a direction parallel to the surface of the piezoelectric substrate 120. Due to the high dielectric constant of the piezoelectric plate 20, the electric field may be highly concentrated and distributed within the piezoelectric plate 20 compared to air. The electric field in the x-direction may cause shear deformation. Thus, it may strongly excite the fundamental shear acoustic mode within the piezoelectric plate 20. In the present invention, “shear deformation” is defined as a deformation in which, during deformation, parallel faces in a material remain parallel to each other and maintain a constant distance apart. “Shear acoustic mode” is defined as a mode of acoustic vibration of a medium that causes shear deformation of the medium. The atomic motion due to shear deformation of the elastic wave elements BF1 to BF4 is mostly in the x-direction, but the direction of acoustic energy flow of the excited fundamental shear acoustic mode may be in the thickness direction of the piezoelectric plate 20.

As described above, the present invention eliminates the need to use an etching hole through the piezoelectric plate as is conventionally done, since the sacrificial material in the cavity is removed through the first connection hole 50, and since the etching hole is not used, damage to the piezoelectric plate may be minimized. Furthermore, the distortion of the acoustic wave excited by the damage of the piezoelectric plate may be minimized, and the required characteristics of the resonator may be satisfied.

Although the present invention uses an etching hole H communicating with the second connecting hole 51, the etching hole H is located in a region not overlapping with the cavity, that is, located between the cavities, so as not to cause distortion to the acoustic wave excited through the piezoelectric diaphragm. In other words, the etching hole H has little effect on the excitation of the acoustic wave in the piezoelectric diaphragm. However, conventionally, the etching hole overlapping the cavity is formed by penetrating the piezoelectric diaphragm, which may affect the excitation of the acoustic wave in the piezoelectric diaphragm and cause distortion of the acoustic wave.

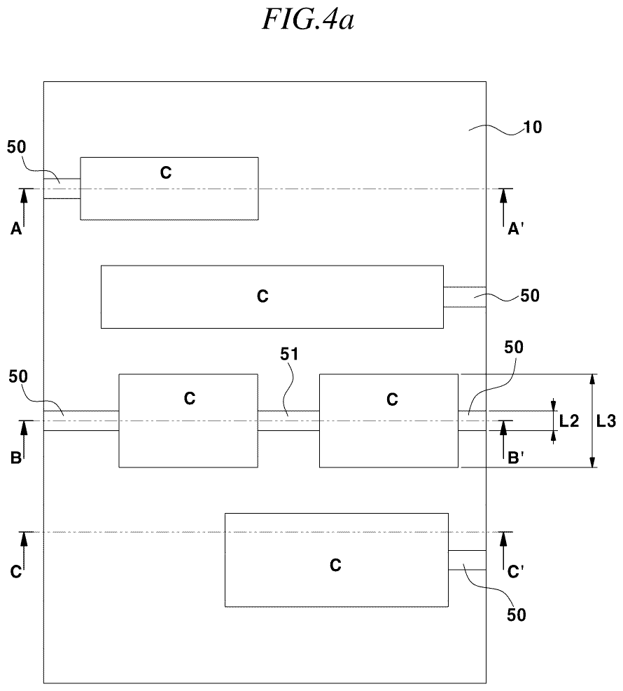

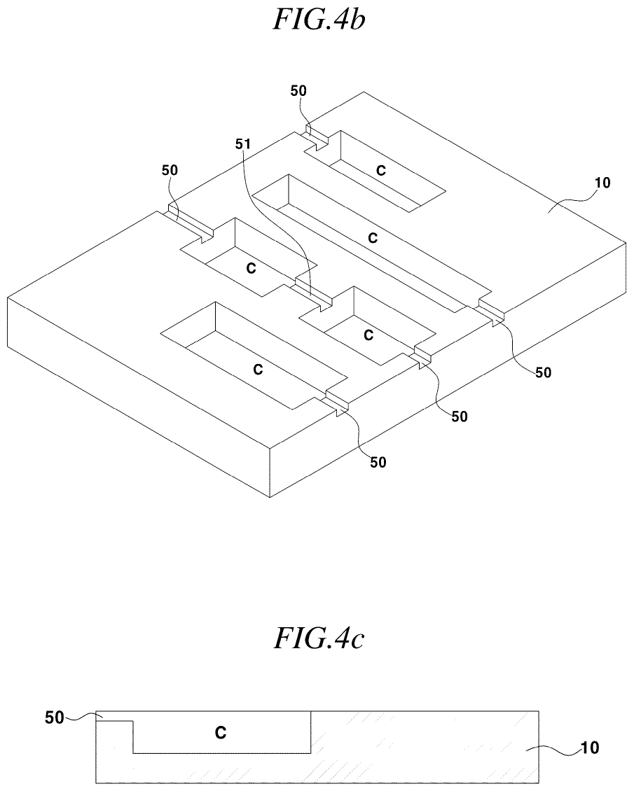

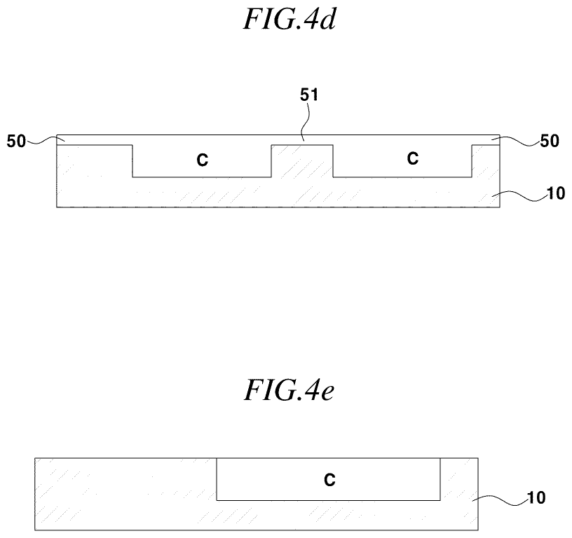

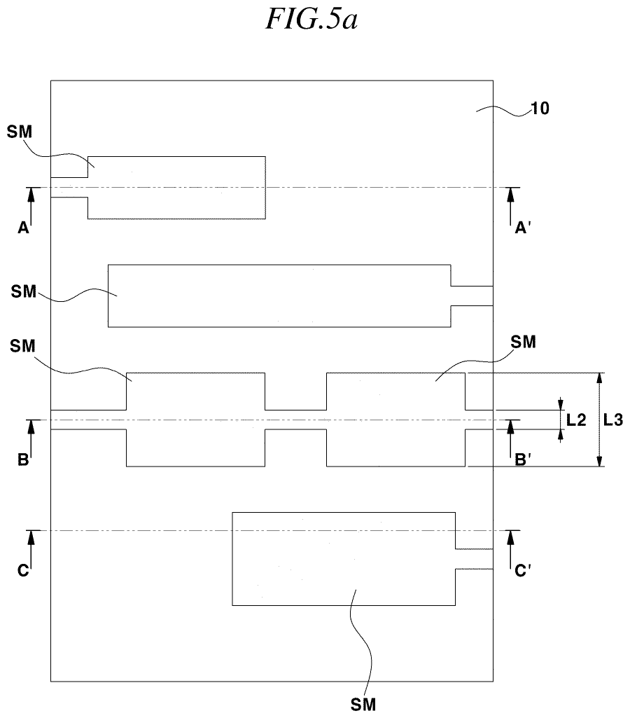

FIGS. 4a through 9e are drawings to illustrate a method of fabricating an RF filter comprising a plurality of elastic wave elements, according to one embodiment of the present invention.

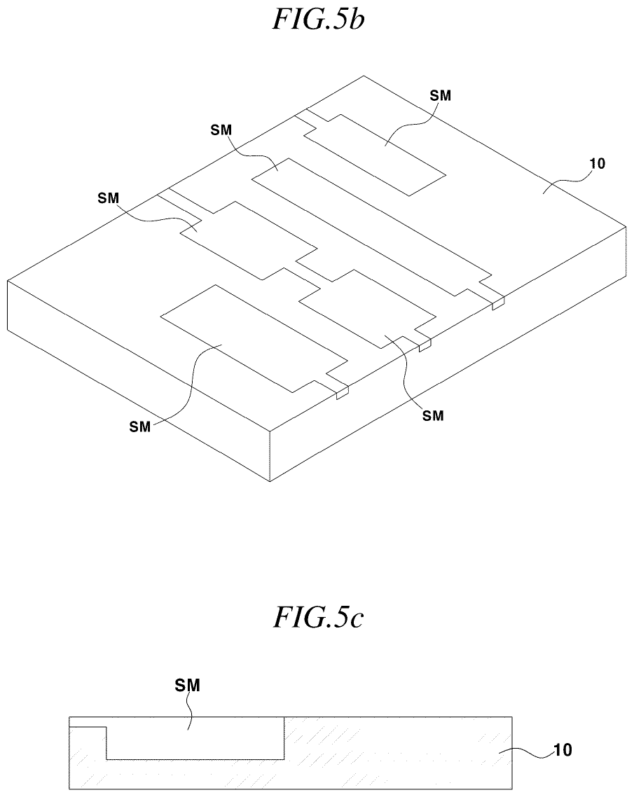

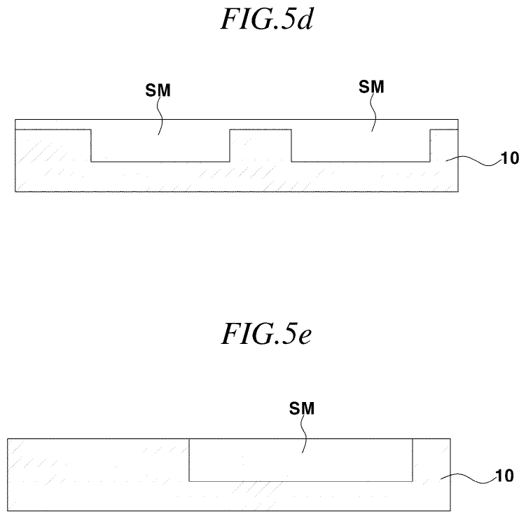

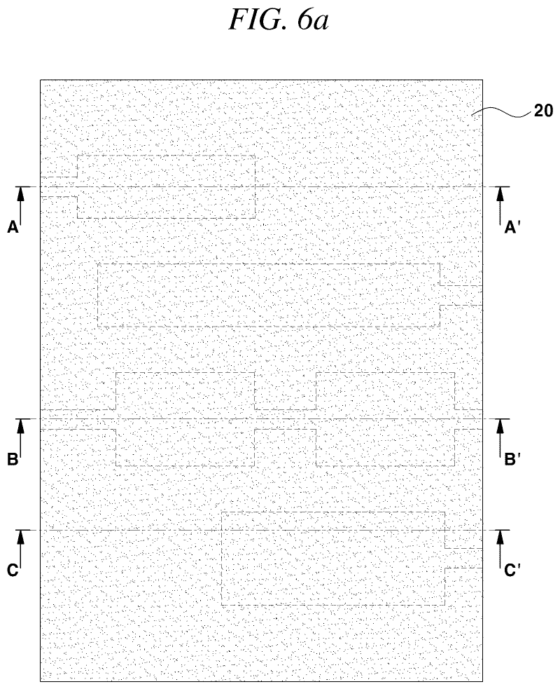

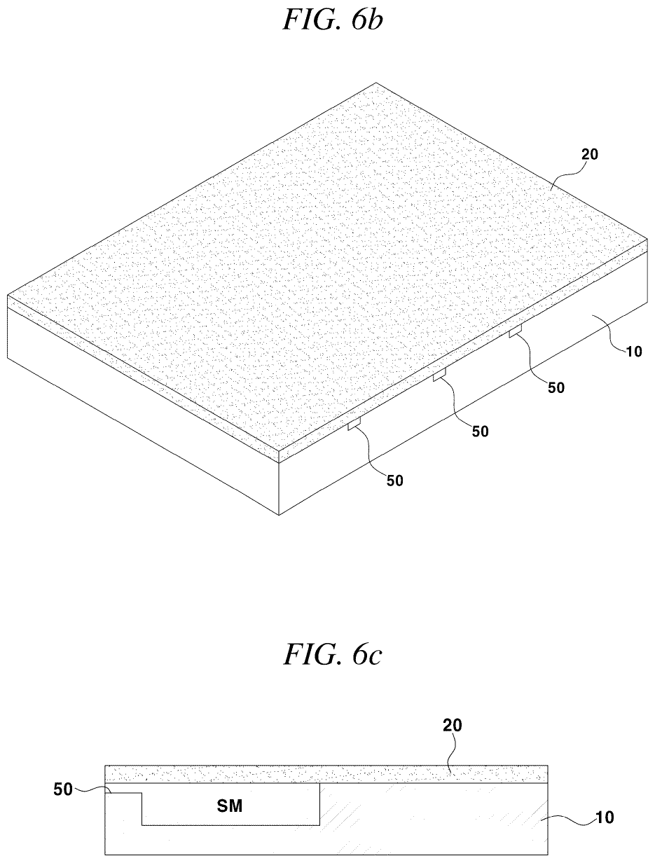

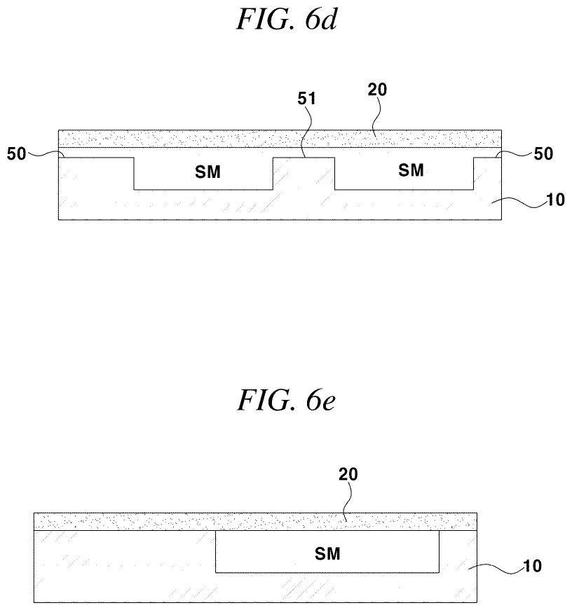

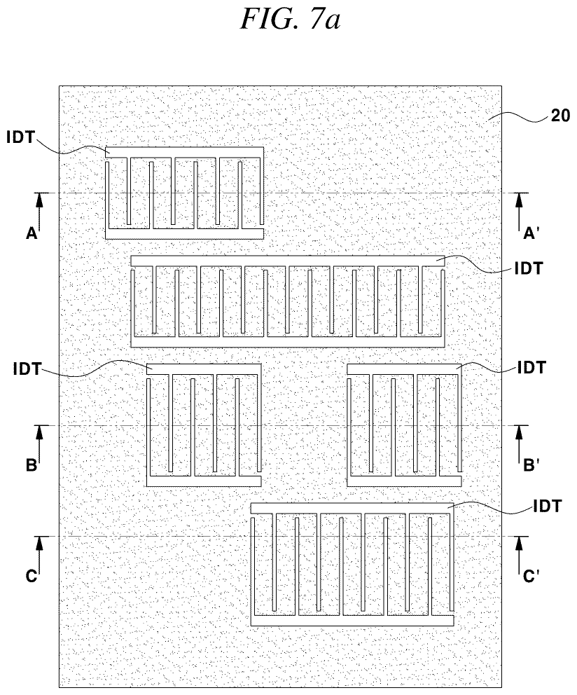

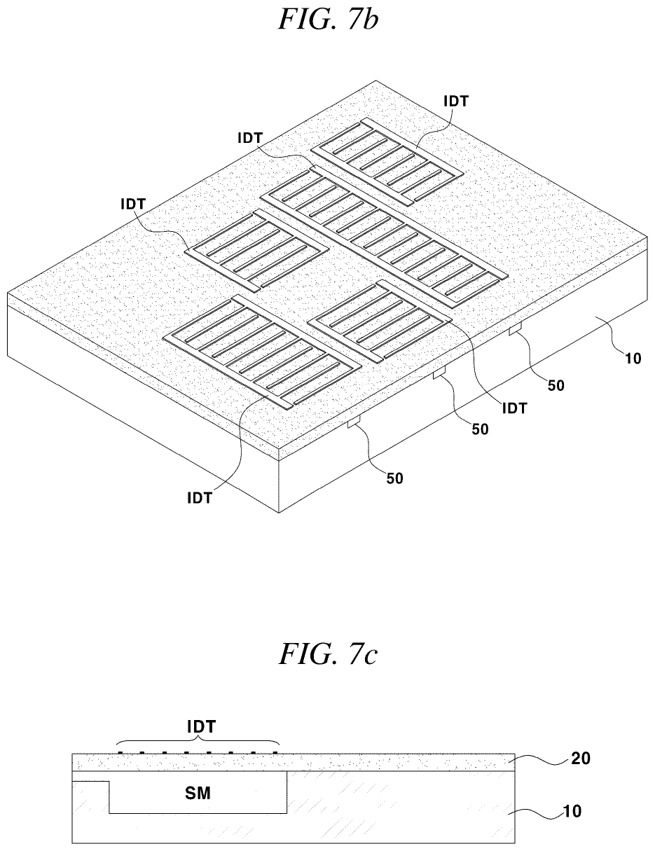

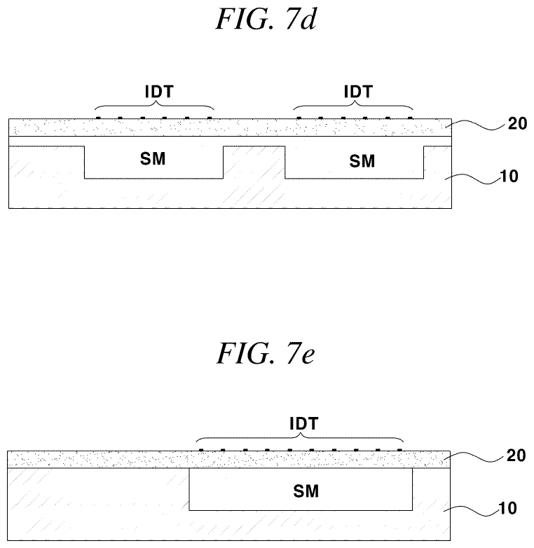

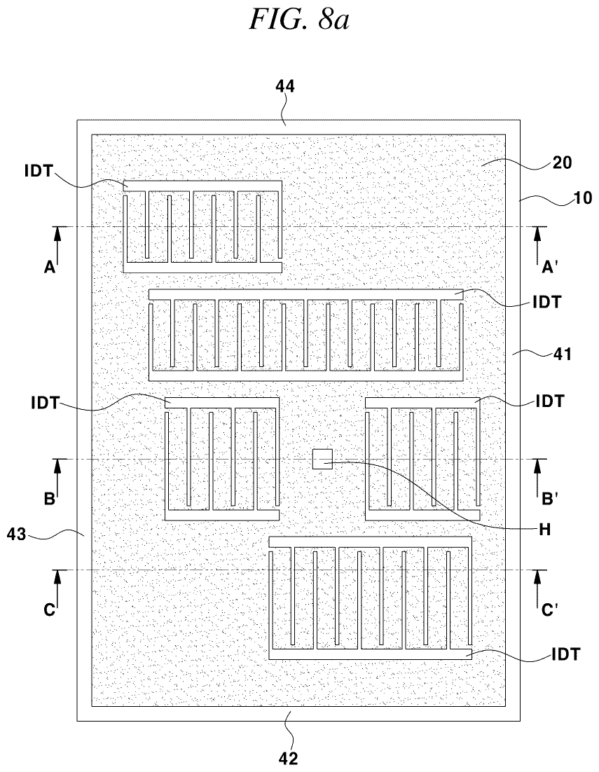

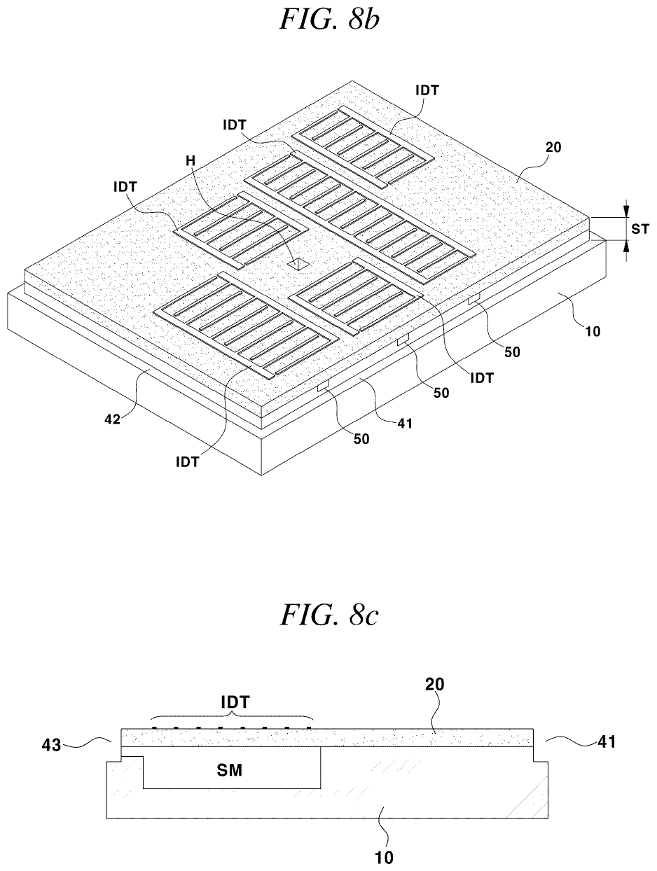

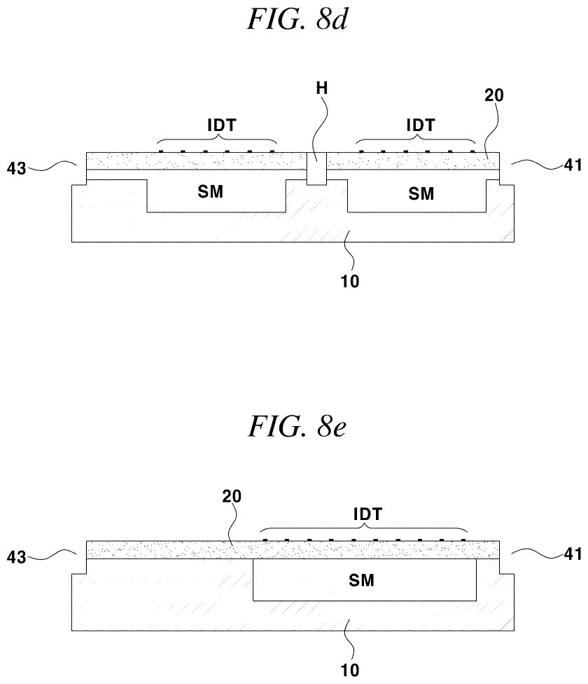

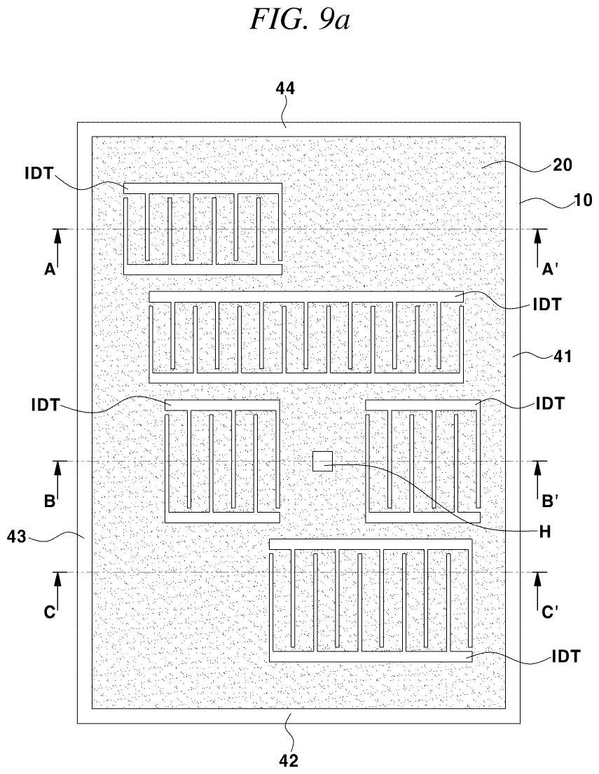

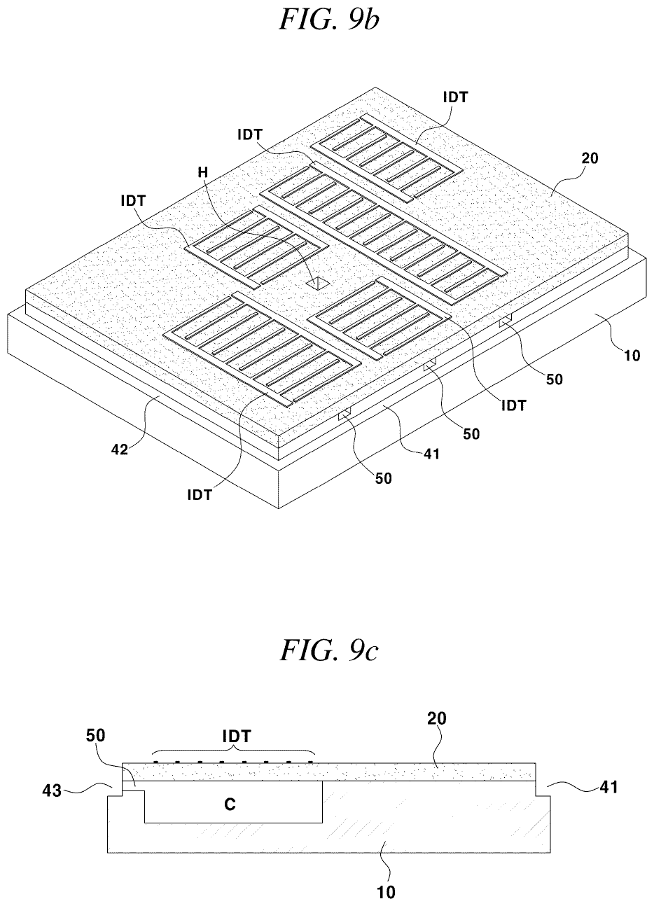

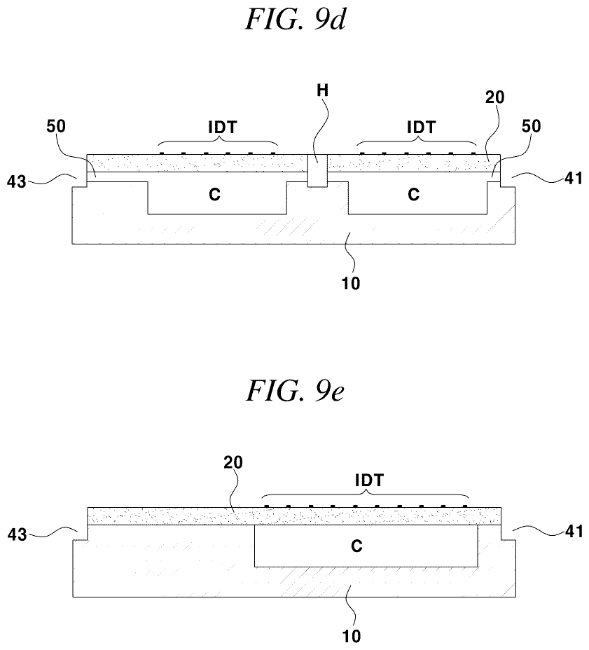

Referring to FIGS. 4a to 9e, the steps of preparing a support substrate having at least one cavity C and at least one horizontal connection hole 50, 51 (FIGS. 4a to 4e); filling the cavity C and the horizontal connection hole 50, 51 with a sacrificial material SM (FIGS. 5a to 5e); and forming a piezoelectric plate 20 on the support substrate 10 where the cavity C and the horizontal connection hole 50, 51 are filled with the sacrificial material SM (FIGS. 6a to 6e); A manufacturing method may be provided that includes the step of forming an open line trench along a peripheral of the support substrate 10 such that the peripheral of the support substrate 10 is exposed (FIGS. 8a to 8e); and an etching step to remove the sacrificial material SM filled in the horizontal connection holes 50, 51 and the cavity C communicating with the open line trench (FIGS. 9a to 9e). The method may further include a step of forming a conductive pattern (plurality of IDTs) in a region of the piezoelectric plate 20 overlapping the cavity C (FIGS. 7a to 7e). The step of forming the conductive patterns (IDTs) may be performed after the step of forming the piezoelectric plate 20 (FIGS. 6a to 6e), after the step of forming the open line trench (FIGS. 8a to 8e), or after the etching step (FIGS. 9a to 9e).

FIG. 4a is a plan view of a support substrate 10 having at least one cavity C and at least one horizontal connection hole 50, 51, FIG. 4b is a perspective view of the support substrate 10, and FIGS. 4c through 4e are cross-sectional views of the support substrate 10. FIG. 4c is a cross-sectional view along line A-A′, FIG. 4d is a cross-sectional view along line B-B′, and FIG. 4e is a cross-sectional view along line C-C′. The first connecting hole 50 is in communication with the cavity C and the open line trench to be described later, and is used to remove the sacrificial material SM filled in the cavity C during the etching process, and the second connecting hole 51 is in communication between the two cavities C, and may be used to remove the sacrificial material SM filled in the cavity C together with the horizontal connecting hole 50 during the etching process. While FIGS. 4a and 4b illustrate, for example, a case where there are five cavities C, five first connecting holes 50, and one second connecting hole 51, the present invention is not limited thereto. The number and arrangement of cavities C, first connection holes 50, and second connection holes 51 may be varied in RF filter design. Also, while the cavity C is shown in FIGS. 4a and 4b as a rectangular shape, the shape of the cavity C may have various polygonal, circular, conical, or trapezoidal shapes. Furthermore, the width and height of the first connecting hole 50 is determined by the distance between the cavity C and the open line trench to be described later, and may therefore be designed to vary depending on the arrangement of the cavity C. Similarly, the width and height of the second connection hole 51 is determined by the distance between the cavities C to be connected, and may therefore be designed to vary depending on the arrangement of the cavities C.

FIG. 5a illustrates a plan view of a support substrate 10 filled with sacrificial material SM in the cavities C and horizontal connection holes 50, 51, FIG. 5b illustrates a perspective view of the support substrate 10 of FIG. 5a, and FIGS. 5c through 5e illustrate cross-sectional views of the support substrate 10 of FIG. 5a. FIG. 5c illustrates a cross-sectional view along line A-A′, FIG. 5d is a cross-sectional view along line B-B′, and FIG. 5e illustrates a cross-sectional view along line C-C′. Non-limitingly, the sacrificial material SM may comprise a silicon oxide film or photoresist. The sacrificial material SM may be a silicon nitride film (Si₃N4) or polysilicon. The photoresist may comprise any one of krypton fluoride (KrF), argon fluoride (ArF), and EUV.

Optionally, the sacrificial material SM may be deposited or coated on the support substrate 10 where the cavity C and the horizontal connection holes 50, 51 are filled with the sacrificial material SM to a thickness of tens nm or less. The purpose is to increase the flattening of the support substrate 10 by thinly coating one side of the support substrate 10 on which the cavity C filled with the sacrificial material SM and the horizontal connection holes 50, 51 are disposed with the sacrificial material SM. When the piezoelectric plate 20 to be described later is deposited on the first surface of the flattened support substrate 10, the piezoelectric plate 20 may have a uniform thickness without protruding.

FIG. 6a illustrates a plan view of an intermediate structure in which the piezoelectric plate 20 is deposited or bonded on the support substrate 10 of FIG. 5a, FIG. 6b illustrates a perspective view of the intermediate structure of FIG. 6a, and FIGS. 6c through 6e illustrate cross-sectional views of the intermediate structure of FIG. 6a. FIG. 6c illustrates a cross-sectional view along the A-A′ line, FIG. 6d illustrates a cross-sectional view along the B-B′ line, and FIG. 6e illustrates a cross-sectional view along the C-C′ line.

The piezoelectric plate 20 may be deposited or coated on the support substrate 10. Alternatively, the support substrate 10 and the piezoelectric plate 20 may be bonded to each other by an inorganic or organic material. The piezoelectric plate 20 may be made of lithium niobate (LiNbO₃), lithium tantalate, lanthanum gallium silicate, gallium nitride, or aluminum nitride, zinc oxide, or lead titanate (PZT). Preferably, the piezoelectric plate 20 may be composed of lithium niobate (LiNbO₃). The thickness of the piezoelectric plate 20, which is bonded to one side of the support substrate 10, may range from 10 nm to 500 nm. If the thickness of the piezoelectric plate 20 is 10 nm or less, it may be difficult to handle during the manufacturing process and may break easily, and if it is 500 nm or more, it may be difficult to realize an RF filter that operates in the desired high and high frequency bands.

FIG. 7a illustrates a top view of RF filter 100 with conductive patterns (IDT electrodes) formed on the intermediate structure of FIG. 6a, FIG. 7b illustrates a perspective view of RF filter 100 of FIG. 7a, and FIGS. 7c through 7e illustrate cross-sectional views of RF filter 100 of FIG. 7a. FIG. 7c illustrates a cross-sectional view along the A-A′ line, FIG. 7d illustrates a cross-sectional view along the B-B′ line, and FIG. 7e illustrates a cross-sectional view along the C-C′ line.

In the present invention, the conductive pattern is defined by a plurality of IDT electrodes formed on the piezoelectric plate 20, wherein five IDT electrodes may be arranged to overlap the cavity C, respectively. While FIGS. 7a and 7b illustrate the case of five IDT electrodes, the present invention is not limited thereto. The number and arrangement of the IDT electrodes to overlap with the cavity C may be varied in the RF filter design.

FIG. 8a illustrates a plan view of RF filter 100 with open line trenches formed along the peripheral, FIG. 8b illustrates a perspective view of RF filter 100 of FIG. 8a, and FIGS. 8c through 8e illustrate cross-sectional views of RF filter 100 of FIG. 8a. FIG. 8c illustrates a cross-sectional view along the A-A′ line, FIG. 8d illustrates a cross-sectional view along the B-B′ line, and FIG. 8e illustrates a cross-sectional view along the C-C′ line.

An open line trench may be formed along the perimeter of the support substrate 10 of FIG. 6a or FIG. 7a. The open line trench may be made by digging a predetermined width L1 of the peripheral of the piezoelectric plate 20 along the peripheral using a trenching method to form a groove. Alternatively, and non-limitingly, the open line trench may be formed during the dicing process. The open line trench may comprise a first line trench 41 on the left, a second line trench 42 on the bottom, a third line trench 43 on the right, and a fourth line trench 44 on the top. The ends of the line trenches 41 to 44 may or may not be connected to each other, and the open line trench may comprise only one of the line trenches 41 to 44 depending on the placement of the cavity C or IDT electrodes.

Furthermore, referring to FIGS. 8a and 8d, an etch hole H may be formed between the two cavities C and the second connecting hole 51 that connects the two cavities C. While FIGS. 8a and 8b illustrate an example of a single etching hole H, the present invention is not limited thereto. In RF filter design, the number and arrangement of etching holes H may be varied depending on the structure of the elastic wave element BF. In a departure from the prior art, the etching holes H do not overlap with the cavity C, but may be formed in a region overlapping with the second connecting hole 51.

The etching hole H may penetrate the piezoelectric plate 20 at least in the thickness direction, exposing at least a portion of the second connecting hole 51 to the outside. An etch gas or etch solution may be delivered to the exposed area to remove the sacrificial material SM in the second connection hole 51 as well as in the two cavities C communicating with the second connection hole 51. In an implementation, the etch holes H may at least partially penetrate the second connecting hole 51 as well as the piezoelectric plate 20 in the thickness direction.

Further, a first portion of the first connection hole 50 may be open via an open line trench. Specifically, the first connection hole 50 may have a cross-sectional area of the end perpendicular to the horizontal exposed to the outside. Etching gas or etching solution may then be injected through the vertical cross-sectional area of the first connection hole 50 exposed to the outside as described above to remove the sacrificial material SM in the first connection hole 50 as well as in the cavity C communicating with the first connection hole 50.

The open line trench also allows for a step ST between the piezoelectric plate 20 and the support substrate 10. The step ST may be equal to or greater than the sum of the thickness of the piezoelectric plate 20 and the height of the first connecting hole h1. The height h1 of the first connecting hole 50 may be less than or equal to the height h2 of the cavity. Further, the height H1 of the first connecting hole 50 may be from 0.2 times to 1.0 times of the height of the open line trench H3. If the height h1 of the first connecting hole 50 is 0.2 times or less than the height of the open line trench h3, it becomes difficult to remove the sacrificial material in the cavity C through the etching gas or etching solution, and if the height h1 of the first connecting hole 50 is 1.0 times or more than the height of the open line trench h3, additional processes are required, which may increase the process cost. Further, the width L2 of the first connection hole 50 may be from 0.1 times to 0.9 times of the width L2 of the cavity C. If the width L2 of the first connecting hole 50 is less than or equal to 0.1 times the width L2 of the cavity C, it becomes difficult to remove the sacrificial material in the cavity C through the etching gas or etching solution, and if the width L2 of the first connecting hole 50 is greater than or equal to 0.9 times or more of the width L2 of the cavity C, the asymmetry with respect to the left and right sides of the cavity C increases, resulting in a decrease in the performance of the filter and a weakening of the stability of the structure, and an additional process of filling the holes may be required.

FIG. 9a illustrates a plan view of RF filter 100 with an open line trench formed along the peripheral, FIG. 9b illustrates a perspective view of RF filter 100 of FIG. 9a, and FIGS. 9c through 9e illustrate cross-sectional views of RF filter 100 of FIG. 9a. FIG. 9c illustrates a cross-sectional view along the A-A′ line, FIG. 9d illustrates a cross-sectional view along the B-B′ line, and FIG. 9e illustrates a cross-sectional view along the C-C′ line.

The first connection hole 50 may be exposed to the outside via an open line trench, and the second connection hole 51 may be exposed to the outside via an etched hole H. By supplying an etching gas or etching solution through the externally exposed first connection hole 50 and second connection hole 51, the first connection hole 50 and second connection hole 51, as well as the sacrificial material SM filled in the cavity C communicating with the first connection hole 50 and second connection hole 51, may be removed. The etching gas or etching solution may comprise HF (hydrofluoric acid), NH₄F(ammonium fluoride), CH₃COOH (acetic acid), H₃PO₄ (phosphoric acid), CH₂H₃O₂ (acetic acid), HNO₃ (nitric acid), CI₂, CF₂, CF₄, SF₆, HBr (hydrogen bromide), CHF₃ fluorine), Ar (argon), H₂(hydrogen), or any one of a combination thereof.

Preferred embodiments of the present invention have been disclosed herein, and although certain terms are used, they are used in a general sense to facilitate the description and understanding of the invention and are not intended to limit the scope of the invention. In addition to the embodiments disclosed herein, other modifications based on the technical ideas of the present invention are possible, as will be apparent to those of ordinary skill in the art to which the present invention belongs. It will be apparent to one having ordinary knowledge in the art that the RF filter and the method of manufacturing the RF filter according to the embodiments described with reference to FIGS. 1 to 8e may be variously substituted, altered and modified without departing from the technical idea of the invention. The scope of the invention is therefore not to be defined by the embodiments described, but by the technical idea recited in the patent claims.

1. An RF filter, comprising:
a support substrate having a plurality of cavities;
a piezoelectric plate disposed on the support substrate;
a conductive pattern disposed on the piezoelectric plate and comprising at least one IDT electrode;
an open line trench exposing a peripheral of the support substrate; and
at least one first connection hole communicating the cavity with the open line trench.

2. The RF filter of claim 1, wherein the open line trench has a step between the piezoelectric plate and the support substrate, and the step is equal to or greater than the sum of a thickness of the piezoelectric plate and a height of the first connection hole.

3. The RF filter of claim 1, wherein the open line trench has a predetermined width and is formed along a peripheral of the support substrate.

4. The RF filter of claim 1, wherein the first connection hole is in a direction perpendicular to a thickness direction of the support substrate.

5. The RF filter of claim 1, wherein a height of the first connecting hole is less than or equal to a height of the cavity.

6. The RF filter of claim 1, wherein a height of the first connection hole is from 0.2 times to 1.0 times a height of the open line trench.

7. The RF filter of claim 1, wherein a width of the first connection hole is from 0.1 times to 0.9 times of a width of the cavity.

8. The RF filter of claim 1, wherein a region of the piezoelectric plate overlapping the at least one cavity and an IDT electrode disposed in the region of the piezoelectric plate are defined by a single bulk elastic wave element, and the RF filter comprises a plurality of the bulk elastic wave elements.

9. The RF filter of claim 1, wherein the bulk elastic wave element comprises two cavities spaced apart from each other, and further comprises a second connecting hole communicating between the two cavities in the bulk elastic wave element.

10. The RF filter of claim 1, wherein the piezoelectric plate comprises any one of lithium niobate (LiNbO₃), lithium tantalate, lanthanum gallium silicate, gallium nitride, or aluminum nitride, zinc oxide, or lead titanate (PZT), and the IDT electrode is an alloy based on any one of Al (aluminum), Cu (copper), Pt (platinum), Au (gold), Ag (silver), Ti (titanium), Ni (nickel), Cr (chromium), Mo (molybdenum), W (tungsten), or any one of these metals, and the support substrate comprises any one of silicon (Si), quartz, glass, silicon carbide (SiC), and sapphire.

11. The RF filter of claim 1, wherein the RF filter is any one of a band reject filter, a band pass filter, a duplexer, and a multiplexer.

12. A method of manufacturing an RF filter, comprising:
preparing a support substrate having at least one cavity and at least one first connecting hole;
filling the cavity and the first connecting hole with a sacrificial material;
forming a piezoelectric plate on the support substrate filled with the sacrificial material;
forming an open line trench along a perimeter of the support substrate such that the perimeter of the support substrate is exposed; and
etching to remove the sacrificial material filled in the cavity and the first connection hole communicating with the open line trench, and
wherein a first end of the first connecting hole is open through the open line trench.

13. The method of claim 12, further comprising:
forming a conductive pattern on a region of the piezoelectric plate overlapping the cavity.

14. The method of claim 12, wherein the sacrificial material is a silicon oxide film or photoresist.

15. The method of claim 12, wherein the support substrate further comprises a second connecting hole communicating between two adjacent cavities.

16. The method of claim 12, wherein a height of the first connecting hole is less than or equal to a height of the cavity.

17. The method of claim 12, wherein the first connection hole has a height of 0.2 times to 1.0 times of a height of the open line trench.

18. The method of claim 12, wherein a width of the first connecting hole is from 0.1 times to 0.9 times of a width of the cavity.

19. An elastic wave element, comprising:
a support substrate having at least one cavity;
a piezoelectric plate disposed on the support substrate;
at least one IDT electrode disposed on the piezoelectric plate; and
at least one first connection hole perpendicular to a thickness direction of the piezoelectric plate, and communicating the cavity to the outside.
